(19) United States
(12) Patent Application Publication
(10) Pub. No.: US 2022/0104340 A1
(43) Pub. Date: Mar. 31, 2022

(54) ELECTRONIC CONTROL DEVICE

(71) Applicant: HITACHI ASTEMO, LTD., Hitachinaka-shi, Ibaraki (JP)

(72) Inventor: Naoki MORIYAMA, Hitachinaka-shi, Ibaraki (JP)

(73) Assignee: HITACHI ASTEMO, LTD., Hitachinaka-shi, Ibaraki (JP)

(21) Appl. No.: 17/420,978

(22) PCT Filed: Nov. 5, 2019
(86) PCT No.: PCT/JP2019/043228

§ 371 Date: Jul. 6, 2021

(30) Foreign Application Priority Data
Jan. 8, 2019 (JP) 2019-000933

(51) Int. Cl. H05K 1/02; H01G 9/12; H01G 9/00

(52) U.S. Cl. CPC H05K 1/0209; H05K 2201/10015; H01G 9/0003; H01G 9/12

(57) ABSTRACT

An electronic control device includes: a circuit board to which electronic components are mounted; an electrolytic capacitor that is mounted to the circuit board, and includes a bottom facing the circuit board, and includes a pressure reduction mechanism disposed in the bottom and structured to release internal pressure of the electrolytic capacitor; and a housing containing the circuit board. The housing includes a pocket that opens at a position to face the electrolytic capacitor mounted to the circuit board and contains the electrolytic capacitor. The pocket includes in its inner periphery a bottom wall surface and a side wall surface that surround the electrolytic capacitor. The electrolytic capacitor is covered by heat dissipation material filling a space between the pocket and a part of the electrolytic capacitor wherein the part faces the bottom wall surface and the side wall surface of the pocket.

### TECHNICAL FIELD

The present invention relates to an electronic control device.

### BACKGROUND ART

Patent Document 1 discloses an electronic device including a metallic container case, a circuit board fixed inside the container case, and electronic components mounted to the circuit board, wherein the electronic components include a heat-generating component such as a choke coil and a low-heat-generating component such as an electrolytic capacitor provided with an explosion proof valve at a front end thereof.

The electronic device of Patent Document 1 further includes heat dissipation resin contained in the container case in order to embed in the heat dissipation resin a front end of the heat-generating component such as the choke coil, and includes a bottomed-tubular protector mounted to the front end of the electrolytic capacitor in order to prevent direct contact between the electrolytic capacitor and the heat dissipation resin.

However, the electronic device of Patent Document 1 has an air layer between the front end of the electrolytic capacitor and the protector covering it, whereas the heat dissipation resin fills the container case with an amount sufficient for the embedment of the front end of the heat-generating component such as the choke coil. This makes it harder for the electronic device of Patent Document 1 to release heat generated in the electrolytic capacitor toward the container case via the heat dissipation resin.

### PRIOR ART DOCUMENT(S)

### Patent Document(s)

Patent Document 1: JP 2014-99550 A

### SUMMARY OF THE INVENTION

According to one aspect of the present invention, an electronic control device includes: a circuit board to which electronic components are mounted; an electrolytic capacitor that is mounted to the circuit board, and includes a bottom facing the circuit board, and includes a pressure reduction mechanism disposed in the bottom and structured to release internal pressure of the electrolytic capacitor; and a housing containing the circuit board. The housing includes a pocket that opens at a position to face the electrolytic capacitor mounted to the circuit board and contains the electrolytic capacitor. The pocket includes in its inner periphery a bottom wall surface and a side wall surface that surround the electrolytic capacitor. The electrolytic capacitor is covered by heat dissipation material filling a space between the pocket and a part of the electrolytic capacitor wherein the part faces the bottom wall surface and the side wall surface of the pocket.

According to the above aspect of the present invention, the heat dissipation material is filled in the pocket containing the electrolytic capacitor. This serves to secure an adequate amount of the heat dissipation material for heat dissipation in the electrolytic capacitor, while avoiding increase in consumption of the heat dissipation material, and thereby facilitate efficient release of heat generated in the electrolytic capacitor toward the housing.

### BRIEF DESCRIPTION OF THE DRAWINGS

FIG. 1 is an illustrative view schematically showing an electronic control device according to a first embodiment of the present invention.

FIG. 2 is a plan view of a housing employed in the electronic control device according to the first embodiment of the present invention.

FIG. 3 is a perspective view of an electrolytic capacitor employed in the electronic control device.

FIG. 4 is an illustrative view schematically showing an electronic control device according to a second embodiment of the present invention.

FIG. 5 is a plan view of a housing employed in the electronic control device according to the second embodiment of the present invention.

### MODE(S) FOR CARRYING OUT THE INVENTION

The following details a first embodiment of the present invention, with reference to the drawings.

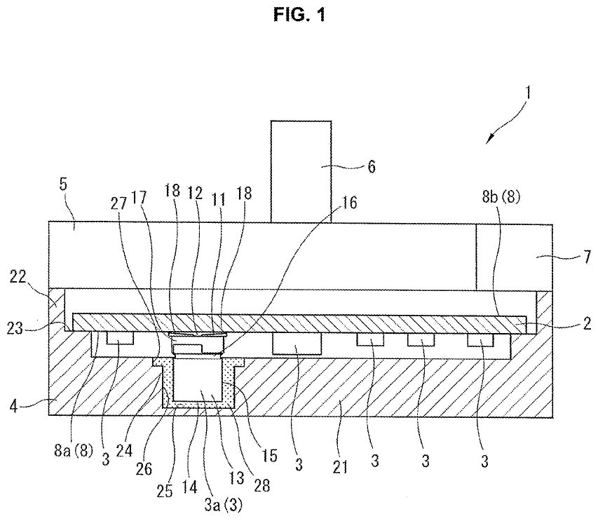

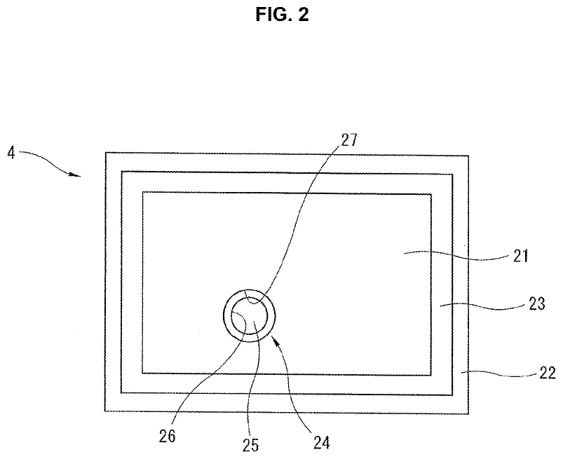

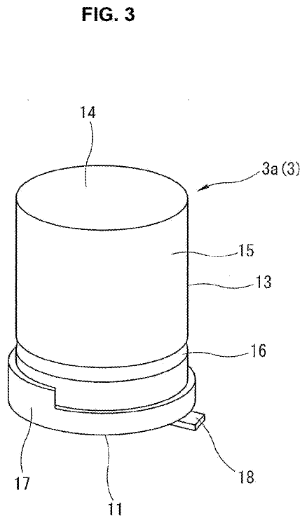

FIG. 1 is an illustrative view schematically showing an electronic control device 1 according to the first embodiment of the present invention. FIG. 2 is a plan view of a housing 4 employed in electronic control device 1 according to the first embodiment of the present invention. FIG. 3 is a perspective view of an electrolytic capacitor 3a employed in electronic control device 1.

Electronic control device 1 is, for example, one for a valve timing changing device of an internal combustion engine mounted in a vehicle such as an automobile. The valve timing changing device is known as disclosed by documents such as JP 2016-169741. The valve timing changing device therein is structured to transfer a rotational force from a motor to a cam shaft via a speed reducer, and change a valve timing by changing a relative rotational phase of the cam shaft with respect to a sprocket receiving the rotational force from a crank shaft.

As shown in FIG. 1, electronic control device 1 includes a circuit board 2, a plurality of electronic components 3 mounted to circuit board 2, and a metallic housing 4 containing circuit board 2. Housing 4 is fixed to a motor housing 5 containing an electric motor not shown. Motor housing 5 is provided with a rotational shaft 6 projecting from motor housing 5. Rotational shaft 6 is connected to a speed reducer not shown. The speed reducer includes an output shaft not shown connected to a cam shaft not shown. In addition, FIG. 1 shows a reference numeral 7 representing a connector section into which a connector from the outside not shown such as a power connector or a signal connector is inserted and connected.

Electronic control device 1 is eventually integrated with the motor housing 5, the electric motor, and the speed reducer so as to compose a valve timing changing device with a so-called electromechanical integrated structure.

As shown in FIG. 1, electronic control device 1 includes an electrolytic capacitor 3a that is one of electronic components 3. Electrolytic capacitor 3a is a heat-generating component that generates heat during operation of electronic control device 1.

As shown in FIGS. 1 and 3, electrolytic capacitor 3a may be specifically a capacitor such as an aluminum electrolytic capacitor or a hybrid capacitor.

Electrolytic capacitor 3a employed in electronic control device 1 is a small-sized cylindrical electrolytic capacitor with, for example, an outer diameter equal to or smaller than 8 mm, and includes a bottom 11 and a pressure reduction mechanism 12 disposed in bottom 11. Bottom 11 faces electronic component mounting surfaces 8 of circuit board 2. Pressure reduction mechanism 12 is structured to release internal pressure of electrolytic capacitor 3a.

Electrolytic capacitor 3a includes a metallic case 13 inside which an electrode, electrolyte, etc. not shown are sealed with a rubber lid not shown. Pressure reduction mechanism 12 is disposed in this lid.

Case 13 has a shape of a bottomed cylinder, and includes a front end (or a front end surface) 14 and a side wall (or a side surface) 15 of electrolytic capacitor 3a.

Side wall 15 of electrolytic capacitor 3a includes an annular depression 16 formed by crimping the case 13 upon the sealing of the electrode, the electrolyte, etc. with the lid. Depression 16 extends continuously throughout an entire circumference of side wall 15.

The lid is positioned in a back side of depression 16 (i.e. an internal side of case 13 behind depression 16). Accordingly, the electrode, the electrolyte, etc. of electrolytic capacitor 3a are positioned nearer to front end 14 than depression 16: i.e., positioned above depression 16 in FIG. 3, and positioned below depression 16 in FIG. 1. Thus, electrolytic capacitor 3a generates heat in a part nearer to front end 14 than depression 16. In other words, the heat-generating part of electrolytic capacitor 3a is a part in such a front end side.

Electrolytic capacitor 3a includes a resin seat 17 at an end thereof that faces circuit board 2 in a state in which electrolytic capacitor 3a is mounted to circuit board 2. Bottom 11 of electrolytic capacitor 3a is substantially composed of the seat 17 and the lid.

Seat 17 serves to suppress electrolytic capacitor 3a from toppling, in the state in which electrolytic capacitor 3a is mounted to circuit board 2. Seat 17 is positioned nearer to bottom 11 of electrolytic capacitor 3a than depression 16. In other words, seat 17 is positioned nearer to an opening of case 13 than depression 16. In addition, seat 17 is structured to avoid impeding the internal pressure release from pressure reduction mechanism 12. For example, seat 17 includes a through hole not shown at a position to face the pressure reduction mechanism 12.

Electrolytic capacitor 3a includes a terminal 18 extending through seat 17. Terminal 18 is soldered to a first electronic component mounting surface 8a that is one of electronic component mounting surfaces 8 of circuit board 2. Furthermore, terminal 18 extends through the lid, and is connected to the electrode. Incrementally, the other of electronic component mounting surfaces 8 is a second electronic component mounting surface 8b in an opposite face to first electronic component mounting surface 8a.

As shown in FIGS. 1 and 2, housing 4 has a shape of a rectangular dish, and includes a bottom wall 21 facing the first electronic component mounting surface 8a of circuit board 2 and a side wall 22 surrounding the bottom wall 21.

Side wall 22 includes a level difference portion 23 having a shape of a step and supporting an outer peripheral edge of circuit board 2. In other words, housing 4 includes in its outer periphery the step-like level difference portion 23 supporting the outer peripheral edge of circuit board 2.

Bottom wall 21 includes a pocket 24 that opens at a position to face the electrolytic capacitor 3a.

Pocket 24 is structured to contain electrolytic capacitor 3a, and includes a bottom wall surface 25 and a side wall surface 26. Bottom wall surface 25 has a circular shape, and faces front end 14 of electrolytic capacitor 3a. Side wall surface 26 has a tubular shape, and faces side wall 15 of electrolytic capacitor 3a.

Pocket 24 is a depression shaped along an external shape of electrolytic capacitor 3a with a predetermined interval or gap between pocket 24 and electrolytic capacitor 3a. According to the first embodiment, pocket 24 is formed in bottom wall 21 of housing 4 as a non-through hole (i.e. a depressed portion) with a circular cross section.

Pocket 24 is structured to surround the electrolytic capacitor 3a with bottom wall surface 25 and side wall surface 26. Thus, electrolytic capacitor 3a mounted to circuit board 2 is surrounded by bottom wall surface 25 and side wall surface 26 of housing 4, in a state in which circuit board 2 is contained in housing 4. In other words, it is allowed to contain electrolytic capacitor 3a in pocket 24.

Pocket 24 is formed such that side wall surface 26 of pocket 24 does not cover a first part of side wall 15 of electrolytic capacitor 3a where the first part is a part nearer to circuit board 2 (i.e. nearer to bottom 11) than depression 16. In other words, pocket 24 is formed such that side wall surface 26 of pocket 24 covers a second part of side wall 15 of electrolytic capacitor 3a where the second part is a part nearer to front end 14 than depression 16. Thus, pocket 24 is structured to cover the heat-generating part of electrolytic capacitor 3a. In other words, pocket 24 is structured to contain the heat-generating part of electrolytic capacitor 3a.

Pocket 24 includes an opening section 27 via which pocket 24 is inserted into pocket 24. Opening section 27 is defined at an open end of side wall surface 26. In other words, opening section 27 forms the open end of side wall surface 26.

Side wall surface 26 of pocket 24 is shaped as a stepped tubular surface in order to increase opening section 27 in inner diameter. In other words, side wall surface 26 in opening section 27 is expanded to an outer circumferential side continuously throughout an entire circumference thereof, in comparison with side wall surface 26 in a section nearer to bottom wall surface 25 than opening section 27.

As shown in FIG. 1, pocket 24 contains thermal grease 28 serving as heat dissipation material. Thermal grease 28 fills a space between pocket 24 and electrolytic capacitor 3a inserted in pocket 24, without leaving a gap. Thus, thermal grease 28 covers the heat-generating part of electrolytic capacitor 3a.

One method for heat dissipation in electrolytic capacitor 3a is to form housing 4 without pocket 24 and fill an entire surface of bottom wall 21 of housing 4 with thermal grease 28. However, such method of filling the entire surface of bottom wall 21 with thermal grease 28 without forming pocket 24 increases a consumption of thermal grease 28, and is likely to cause rise in cost and increase in weight. Furthermore, due to the increase in consumption of thermal grease 28, the method of filling the entire surface of bottom wall 21 with thermal grease 28 without forming pocket 24 is likely to make it difficult to fill housing 4 with an appropriate amount of thermal grease 28 for the heat dissipation in electrolytic capacitor 3a.

According to the first embodiment, electronic control device 1 is configured such that thermal grease 28 fills pocket 24 containing electrolytic capacitor 3a. This serves to secure an adequate amount of the heat dissipation material for the heat dissipation in the electrolytic capacitor, while suppressing the increase in consumption of thermal grease 28, and thereby allow electronic control device 1 to efficiently release heat generated in electrolytic capacitor 3a toward housing 4.

Electronic control device 1 is structured to efficiently release the heat generated in electrolytic capacitor 3a toward housing 4. This increases the number of choices for electrolytic capacitor 3a employable or applicable in electronic control device 1. Furthermore, such increase in number of employable or applicable choices for electrolytic capacitor 3a allows electronic control device 1 to be more beneficially designed in view of cost, size, electric characteristics, etc. In other words, electronic control device 1 is improved in flexibility of design due to achievement of the efficient release of heat generated in electrolytic capacitor 3a toward housing 4.

Pocket 24 is shaped along the external shape of electrolytic capacitor 3a. Thus, pocket 24 is formed in a size in conformance with a size of electrolytic capacitor 3a contained in pocket 24. This allows optimization of the amount of thermal grease 28 in pocket 24. Accordingly, electronic control device 1 is optimized in consumption of thermal grease 28 for the efficient heat release from electrolytic capacitor 3a toward housing 4, since thermal grease 28 in pocket 24 contributes to the heat release from electrolytic capacitor 3a. In other words, electronic control device 1 is reduced in consumption of thermal grease 28 and thereby reduced in cost and weight, in comparison with a case of, for example, releasing heat from electrolytic capacitor 3a toward housing 4 with use of thermal grease 28 filling the entire surface of housing 4.

In electronic control device 1, pocket 24 containing thermal grease 28 is shaped in conformance with the external shape of electrolytic capacitor 3a. This facilitates the efficient release of heat generated in electrolytic capacitor 3a toward housing 4, even in case that electrolytic capacitor 3a is a small one.

Pocket 24 includes opening section 27 receiving thermal grease 28, wherein opening section 27 is expanded to the outer circumferential side in comparison with side wall surface 26 in the section nearer to bottom wall surface 25. This allows pocket 24 to contain an increased amount of thermal grease 28 in an inner circumferential region of opening section 27. Furthermore, pocket 24 has a depth set such that pressure reduction mechanism 12 of electrolytic capacitor 3a is not contained within pocket 24. The depth of pocket 24 is designed to be equal to a distance from bottom wall surface 25 of pocket 24 to depression 16 of electrolytic capacitor 3a when mounted, or a distance from bottom wall surface 25 of pocket 24 to seat 17 of electrolytic capacitor 3a when mounted. In other words, the depth dimension of pocket 24, i.e. a distance from bottom wall surface 25 of pocket 24 to an open end 29 of pocket 24, is set to be shorter than a distance from bottom wall surface 25 of pocket 24 to pressure reduction mechanism 12 of electrolytic capacitor 3a, wherein open end 29 of pocket 24 is positioned in a plane including an upper surface of bottom wall 21 of housing 4.

Accordingly, electronic control device 1 is configured such that circuit board 2 and thermal grease 28 in pocket 24 define therebetween a space in which pressure reduction mechanism 12 of electrolytic capacitor 3a is positioned.

This serves to suppress electronic control device 1 from undergoing some problems: e.g., suppress pressure reduction mechanism 12 from being covered by surplus thermal grease 28, suppress circuit board 2 from contacting with surplus thermal grease 28, etc. Thus, electronic control device 1 is structured to certainly implement the pressure release by pressure reduction mechanism 12 (i.e. implement operation of pressure reduction mechanism 12).

The following describes another embodiment of the present invention. The same components with the first embodiment above are represented by the same reference numerals, while omitting explanations thereof.

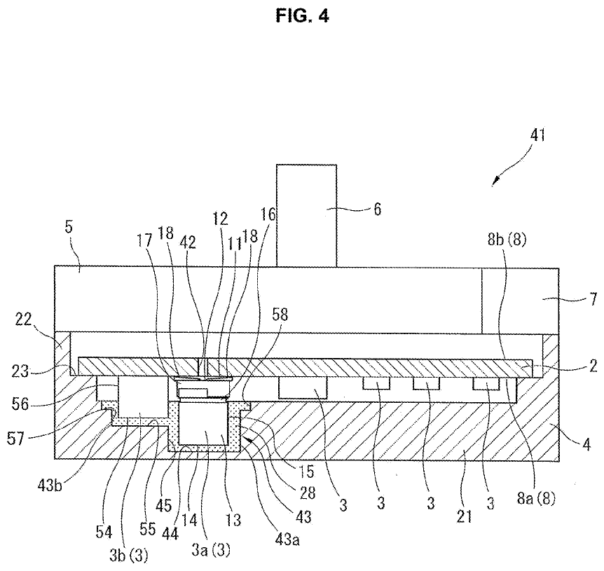

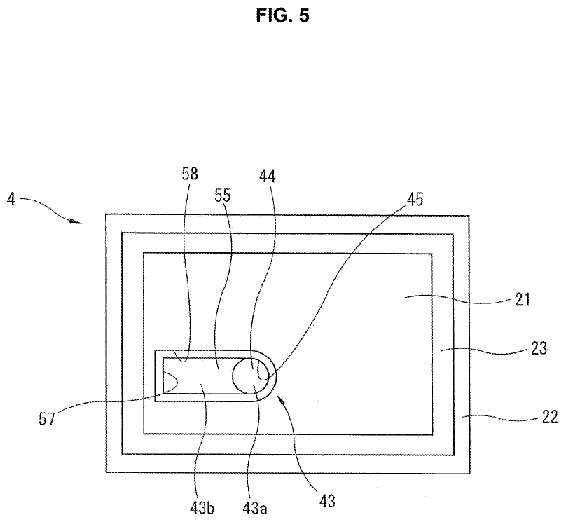

FIGS. 4 and 5 shows an electronic control device 41 according to the second embodiment of the present invention. FIG. 4 is an illustrative view schematically showing electronic control device 41 according to the second embodiment. FIG. 5 is a plan view of housing 4 employed in electronic control device 41 according to the second embodiment.

Electronic control device 41 according to the second embodiment is configured similarly to the first embodiment in major parts, although circuit board 2 according to the second embodiment is provided with a coil unit 3b mounted thereto, as shown in FIG. 4. Moreover, circuit board 2 in electronic control device 41 according to the second embodiment includes a through hole 42 at a position to face bottom 11 of electrolytic capacitor 3a mounted to circuit board 2. Furthermore, as shown in FIGS. 4 and 5, bottom wall 21 of housing 4 in electronic control device 41 includes a pocket 43 that opens at a position to face electrolytic capacitor 3a and coil unit 3b.

Coil unit 3b corresponds to a coil, and is a component having a shape such as a cuboid shape. Coil unit 3b is mounted to first electronic component mounting surface 8a adjacently to electrolytic capacitor 3a, and composes an LC circuit with electrolytic capacitor 3a. Coil unit 3b is a heat-generating component that generates heat during operation of electronic control device 1.

When mounted to circuit board 2, coil unit 3b is less than electrolytic capacitor 3a in amount of projection from first electronic component mounting surface 8a. In other words, coil unit 3b is lower in height than electrolytic capacitor 3a, according to the second embodiment.

As shown in FIG. 5, pocket 43 has a shape of a combination of a circle and a rectangle. Pocket 43 is a depression shaped along external shapes of electrolytic capacitor 3a and coil unit 3b so as to form a predetermined interval or gap with electrolytic capacitor 3a and coil unit 3b.

Pocket 43 according to the second embodiment includes an electrolytic capacitor container 43a and a coil unit container 43b. Electrolytic capacitor container 43a is formed in bottom wall 21 of housing 4 as a non-through hole (i.e. a depressed portion) having a circular cross section. Coil unit container 43b is formed in bottom wall 21 of housing 4 as a non-through hole (i.e. a depressed portion) having a rectangular cross section. In other words, pocket 43 according to the second embodiment is formed in bottom wall 21 of housing 4 as a combination of the non-through hole with the circular cross section and the non-through hole with the rectangular cross section.

Electrolytic capacitor container 43a is structured to contain electrolytic capacitor 3a, and includes a bottom wall surface 44 facing front end 14 of electrolytic capacitor 3a and a side wall surface 45 facing side wall 15 of electrolytic capacitor 3a.

Electrolytic capacitor container 43a is structured to surround electrolytic capacitor 3a with bottom wall surface 44 and side wall surface 45. In the state in which circuit board 2 is contained in housing 4, electrolytic capacitor 3a mounted to circuit board 2 is surrounded by bottom wall surface 44 and side wall surface 45 of electrolytic capacitor container 43a. In other words, it is allowed to contain electrolytic capacitor 3a in electrolytic capacitor container 43a.

Electrolytic capacitor container 43a is formed such that side wall surface 45 of electrolytic capacitor container 43a does not cover the first part of side wall 15 of electrolytic capacitor 3a where the first part is the part nearer to circuit board 2 (i.e. nearer to bottom 11 of electrolytic capacitor 3a) than depression 16 of electrolytic capacitor 3a. In other words, electrolytic capacitor container 43a is formed such that side wall surface 45 of electrolytic capacitor container 43a covers the second part of side wall 15 of electrolytic capacitor 3a where the second part is the part nearer to front end 14 of electrolytic capacitor 3a than depression 16 of electrolytic capacitor 3a. Thus, electrolytic capacitor container 43a is structured to cover the heat-generating part of electrolytic capacitor 3a. In other words, electrolytic capacitor container 43a is structured to contain the heat-generating part of electrolytic capacitor 3a.

Electrolytic capacitor container 43a is the depression shaped along the external shape of electrolytic capacitor 3a so as to form a predetermined interval or gap with electrolytic capacitor 3a.

Coil unit container 43b is structured to contain coil unit 3b, and includes a bottom wall surface 55 and a side wall surface 57. Bottom wall surface 55 faces a front end 54 of coil unit 3b. Side wall surface 57 faces a side wall 56 of coil unit 3b. Coil unit container 43b is formed continuously with electrolytic capacitor container 43a.

Coil unit container 43b is the depression shaped along the external shape of coil unit 3b so as to form a predetermined interval or gap with coil unit 3b.

Coil unit container 43b is shallower in depth than electrolytic capacitor container 43a, because coil unit 3b is lower in height than electrolytic capacitor 3a.

Pocket 43 includes an opening section 58 via which electrolytic capacitor 3a and coil unit 3b are inserted into pocket 43. Opening section 58 of pocket 43 is defined by open ends of side wall surfaces 45 and 57. In other words, opening section 58 forms the open ends of side wall surfaces 45 and 57.

Side wall surfaces 45 and 57 are shaped to be stepped in order to increase opening section 58 in inside opening area. In other words, opening section 58 of pocket 43 includes an inner peripheral surface that overhangs like a flange toward the outer circumferential side continuously throughout an entire circumference of opening section 58. In detail, pocket 43 is shaped such that: side wall surface 45 in opening section 58 is expanded to the outer circumferential side, in comparison with side wall surface 45 in a section nearer to bottom wall surface 44 than opening section 58; and side wall surface 57 in opening section 58 is expanded to the outer circumferential side, in comparison with side wall surface 57 in a section nearer to bottom wall surface 55 than opening section 58. In still other words, pocket 43 is formed such that opening section 58 has an opening area greater than a sum of a cross sectional area of electrolytic capacitor container 43a in a vicinity of bottom wall surface 44 and a cross sectional area of coil unit container 43b in a vicinity of bottom wall surface 55.

Pocket 43 contains thermal grease 28 serving as heat dissipation material. Thermal grease 28 fills, without leaving a gap, a space between pocket 43 and electrolytic capacitor 3a and coil unit 3b inserted in pocket 43.

Thus, thermal grease 28 covers heat-generating parts of electrolytic capacitor 3a and coil unit 3b.

Electrolytic capacitor container 43a of pocket 43 has a depth set such that pressure reduction mechanism 12 of electrolytic capacitor 3a is not contained within electrolytic capacitor container 43a. The depth of electrolytic capacitor container 43a is designed to be equal to a distance from bottom wall surface 44 of electrolytic capacitor container 43a to depression 16 of electrolytic capacitor 3a when mounted, or a distance from bottom wall surface 44 of electrolytic capacitor container 43a to seat 17 of electrolytic capacitor 3a when mounted. In other words, the depth dimension of electrolytic capacitor container 43a, i.e. a distance from bottom wall surface 44 to open end 46 of pocket 43, is set to be shorter than a distance from bottom wall surface 44 of electrolytic capacitor container 43a to pressure reduction mechanism 12 of electrolytic capacitor 3a, wherein open end 46 of pocket 43 is positioned in the plane including the upper surface of bottom wall 21 of housing 4.

Thus-configured electronic control device 41 according to the second embodiment is capable of presenting beneficial effects similar to the first embodiment described above.

In addition, in electronic control device 41 according to the second embodiment, through hole 42 of circuit board 2 serves to ensure reliable operation of pressure reduction mechanism 12 of electrolytic capacitor 3a. This is because through hole 42 serves as a path for pressure release from pressure reduction mechanism 12, even in case that electrolytic capacitor 3a is entirely surrounded by the heat dissipation material in pocket 43.

Furthermore, electronic control device 41 is configured such that electrolytic capacitor 3a and coil unit 3b adjacent to it are contained in pocket 43. This serves for efficient dissipation of heat generated in electrolytic capacitor 3a and coil unit 3b.

The present invention is not limited to the specific embodiments described above, and may be variously modified within scope of the invention.

For example, although the above embodiments show each of pockets 24 and 43 formed as a depression in bottom wall 21 by utilizing a thickness of bottom wall 21, each of pockets 24 and 43 may be defined by a wall projecting from bottom wall 21. Specifically, pocket 24 or 43 may be defined inside a wall projecting from bottom wall 21 and continuing along an external shape of electrolytic capacitor 3a in a plan view or along external shapes of electrolytic capacitor 3a and coil unit 3b in a plan view.

Circuit board 2 in electronic control device 1 according to the first embodiment may be modified to include through hole 42 at a position to face bottom 11 of electrolytic capacitor 3a when mounted.

The first and second embodiment show pockets 24 and 43 respectively including opening sections 27 and 58 each of which includes the inner peripheral surface expanded to the outer circumferential side continuously throughout the entire circumference. However, the inner peripheral surface of opening section 27 or 58 may be expanded to the outer circumferential side intermittently. Specifically, pocket 24 may be formed such that side wall surface 26 in opening section 27 is partially expanded to the outer circumferential side in comparison with side wall surface 26 in the section nearer to bottom wall surface 25. Pocket 43 may be formed such that side wall surface 45 in opening section 58 is partially expanded to the outer circumferential side in comparison with side wall surface 45 in the section nearer to bottom wall surface 44, and/or such that side wall surface 55 in opening section 58 is partially expanded to the outer circumferential side in comparison with side wall surface 55 in the section nearer to bottom wall surface 54.

The first and second embodiment show pockets 24 and 43 each of which is one in number (i.e., formed at one region). However, a plurality of pockets 24 or 43 may be formed in bottom wall 21 depending on the number of electrolytic capacitors 3a mounted to circuit board 2.

The following exemplifies one aspect of an electronic control device according to the embodiments described above.

An electronic control device includes: a circuit board to which electronic components are mounted; an electrolytic capacitor that is mounted to the circuit board, and includes a bottom facing the circuit board, and includes a pressure reduction mechanism disposed in the bottom and structured to release internal pressure of the electrolytic capacitor; and a housing containing the circuit board, wherein: the housing includes a pocket that opens at a position to face the electrolytic capacitor mounted to the circuit board and contains the electrolytic capacitor; the pocket includes in its inner periphery a bottom wall surface and a side wall surface that surround the electrolytic capacitor; and the electrolytic capacitor is covered by heat dissipation material filling a space between the pocket and a part of the electrolytic capacitor wherein the part faces the bottom wall surface and the side wall surface of the pocket.

Furthermore, the electronic control device above may be carried out according to an embodiment adopting at least one of the following aspects (1) to (7).

(1) The electrolytic capacitor includes a heat-generating part contained in the pocket and covered by the heat dissipation material.

(2) The pocket includes an opening section via which the electrolytic capacitor is inserted into the pocket. The side wall surface of the pocket in the opening section is expanded to an outer circumferential side, in comparison with the side wall surface of the pocket in a section nearer to the bottom wall surface of the pocket than the opening section.

(3) The circuit board includes a through hole at a position to face the bottom of the electrolytic capacitor.

(4) The electrolytic capacitor is a component of an LC circuit, and is contained in the pocket together with a coil mounted to the circuit board adjacently to the electrolytic capacitor.

(5) The circuit board and the heat dissipation material in the pocket define therebetween a space in which the pressure reduction mechanism of the electrolytic capacitor is positioned.

(6) The pocket has a depth dimension shorter than a distance from the bottom wall surface of the pocket to the pressure reduction mechanism of the electrolytic capacitor, where the depth dimension of the pocket is a distance from the bottom wall surface of the pocket to an open end of the pocket

(7) The housing is made of a metal.

1. An electronic control device comprising:
a circuit board to which electronic components are mounted;
an electrolytic capacitor that is mounted to the circuit board, and includes a bottom facing the circuit board, and includes a pressure reduction mechanism disposed in the bottom and structured to release internal pressure of the electrolytic capacitor; and
a housing containing the circuit board,
wherein:
the housing includes a pocket that opens at a position to face the electrolytic capacitor mounted to the circuit board and contains the electrolytic capacitor;
the pocket includes in its inner periphery a bottom wall surface and a side wall surface that surround the electrolytic capacitor; and
the electrolytic capacitor is covered by heat dissipation material filling a space between the pocket and a part of the electrolytic capacitor wherein the part faces the bottom wall surface and the side wall surface of the pocket.

2. The electronic control device as claimed in claim 1, wherein the electrolytic capacitor includes a heat-generating part contained in the pocket and covered by the heat dissipation material.

3. The electronic control device as claimed in claim 1, wherein:
the pocket includes an opening section via which the electrolytic capacitor is inserted into the pocket; and
the side wall surface of the pocket in the opening section is expanded to an outer circumferential side, in comparison with the side wall surface of the pocket in a section nearer to the bottom wall surface of the pocket than the opening section.

4. The electronic control device as claimed in claim 1, wherein the circuit board includes a through hole at a position to face the bottom of the electrolytic capacitor.

5. The electronic control device as claimed in claim 1, wherein the electrolytic capacitor is a component of an LC circuit, and is contained in the pocket together with a coil mounted to the circuit board adjacently to the electrolytic capacitor.

6. The electronic control device as claimed in claim 1, wherein the circuit board and the heat dissipation material in the pocket define therebetween a space in which the pressure reduction mechanism of the electrolytic capacitor is positioned.
